(19) United States
(12) Patent Application Publication
(10) Pub. No.: US 2005/0109278 A1
(43) Pub. Date: May 26, 2005

(54) Method to locally protect extreme ultraviolet multilayer blanks used for lithography

(76) Inventors: Ted Liang, Sunnyvale, CA (US); Alan Stivers, Palo Alto, CA (US)

Correspondence Address: Edwin H. Taylor;Blakely, Sokoloff, Taylor & Zafman LLP, 1279 Oakmead Parkway, Sunnyvale, CA, 94085, US

(21) Appl. No.: 10/723,726

(22) Filed: Nov. 26, 2003

(51) Int. Cl. C23C 16/00; C08J 7/18; C23C 8/00

(52) U.S. Cl. 118/723 FE; 427/561; 427/140; 427/585

(57) ABSTRACT

A method of forming thin films of materials on an extreme ultraviolet multilayer surface is described. Specifically, an electron beam and a precursor gas are used to locally deposit a capping filling in a pinhole of a multilayer surface. The growth rate, purity, and spatial resolution of the capping filling may be modulated.

### FIELD OF THE INVENTION

The present invention pertains to the field of semiconductor processing. More particularly, the present invention relates to a method to perform localized deposition of capping films to protect underlying multilayers.

### BACKGROUND OF THE INVENTION

A transistor is the basic device used to implement a function on an integrated circuit. Transistors in CMOS technology are created using a Metal-Oxide-Silicon (MOS) structure by superimposing several layers of conducting and insulating materials on a substrate in a photolithographic or lithography process.

To create the desired pattern or image on a silicon wafer, the surface layer is covered with a thin film of polymeric film or photoresist that is sensitive to light. The film is then exposed using radiation such as ultraviolet light. The ultraviolet light typically has a spectral range between 150 and 500 nanometers (nm). The ultraviolet light is passed through a patterned mask onto the silicon wafer. The mask protects part of the wafer from the light. The exposed portion is degraded by the light and developed. Chemicals are then used to etch away the developed portions. This process is repeated for each layer added to the wafer.

To increase device performance and to reduce the costs associated with fabricating computer chips, the trend in semiconductor design is towards building smaller transistors. In addition, the demand for greater computing power dictates that more transistors be placed on each chip. Lights with increasingly shorter wavelengths are being used for printing wafers having shrinking features. Lithography using extreme ultraviolet (EUV) light, having a spectral range between 10 and 15 nm, has been used to create computer components having smaller dimensions.

One of the critical elements in EUV lithography is the reflective multilayer blanks. Since solid materials are highly absorptive of EUV light, reflective mirrors and masks are typically used for EUV lithography. These reflective multilayers are made of alternating layers of materials of high and low indices of refraction.

The reflective multilayers are often sensitive to chemicals. Thus, the surface is typically protected with a capping layer. The capping layer is made of materials that are relatively chemically inert and allow a greater transmission of EUV light. Once the capping layer is damaged, the underlying multilayers lose protection and degrade.

### BRIEF DESCRIPTION OF THE DRAWINGS

FIG. 1A is a diagram of a multilayer blank having a pinhole;

FIG. 1B is an embodiment of a deposited capping filling in a pinhole;

FIG. 2 is an apparatus for performing localized deposition of capping filling;

FIG. 3 is a flowchart for performing localized deposition of capping films to unprotected areas of multilayers;

FIG. 4 is a flowchart for adding a capping layer to a multilayer blank; and

FIG. 5 is table of pinhole materials and their corresponding precursor gases.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Light having a wavelength in the EUV spectral range has a high absorptance and cannot pass through a traditional lithography mask that is typically made on a quartz substrate. Thus, the lithography setup in a EUV process is different from that which is traditionally used. The transfer of the pattern from the mask to the resist is made using reflection rather than transmission. In other words, reflective mirrors that are coated with multilayers are used in a stepper to project patterns on a mask onto a target wafer. The mask patterns may be made on reflective multilayer blanks. Multilayer blanks are substrates coated with multilayers. The term multilayer blanks may refer to multilayer coated substrates used for fabricating both EUV mirrors and masks.

The reflective multilayers may be alternating layers of molybdenum and silicon or molybdenum and beryllium. The substrates may comprise any solid materials having a polished smooth surface. Further, the substrates may comprise low thermal expansion materials (LTEM) with very low coefficients of thermal expansion to avoid thermal expansion under EUV illumination. For example, the LTEM materials may be ULE® and Zerodur®. The substrates may be flat or figured (shaped) surfaces.

A capping layer is often disposed on the top of the multilayers to protect the multilayers from being damaged by oxidation in the environment and erosion from processing chemicals used for patterning and cleaning of the masks. For one embodiment of the invention, the capping layer may comprise silicon having a thickness of approximately 4-11 nm. For another embodiment of the invention, the capping layer may comprise ruthenium having a thickness between 2-4 nm. Thicker capping layers may also be used. For yet another embodiment of the invention, the capping layer may comprise carbon.

As stated above, a multilayer blank is the portion of the EUV mask that consists of the substrate and the multilayers. The multilayers may be positioned on top of the substrate. A capping layer protects the multilayers of the multilayer blank. A mask blank comprises a multilayer blank coupled to a buffer layer and an absorber layer. The buffer layer acts as an etch stopper. The absorber is used for the mask pattern to absorb EUV light.

The capping layer is sputtered on the whole surface of the multilayers. If the capping layer is not evenly applied, the multilayers may lose protection as a result of pinholes or surface areas of multilayers not covered by the capping layer. Pinholes may result for a variety of reasons. First, pinholes may be caused by debris particles on the multilayers during the capping layer deposition process. The removal of such debris particles may lead to the formation of pinholes. Second, the capping layer itself is often extremely thin. An uneven distribution of the capping layer may leave areas of the multilayers exposed. Finally, the creation of pinholes and the degradation of the capping layer may be initiated during mask patterning or cleaning. For example, over-etching of the buffer and absorber layers on top of the capping layer may cause multilayers to be exposed.

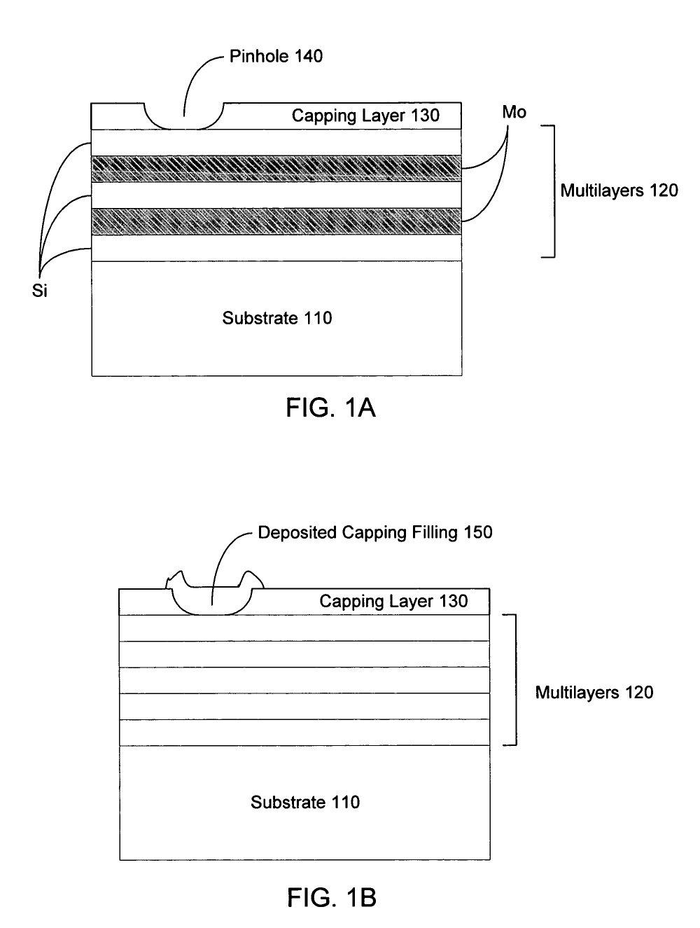

FIG. 1A depicts a diagram of a multilayer blank having a pinhole 140. Substrate 110 is coupled to multilayers 120. Multilayers 120 may comprise 40-50 alternating layers of films. For example, the multilayers 120 may comprise alternating layers of molybdenum and silicon as depicted in FIG. 1A. The multilayers 120, however, are not limited to being molybdenum and silicon. Capping layer 130 is coupled to multilayers 120. To protect the multilayers 120 exposed by the pinhole 140, FIG. 1B depicts a capping filling 150 that may be deposited to the pinhole 140. For one embodiment of the invention, the overlap of the capping filling 150 to the capping layer 130 is kept at a minimum to prevent adverse affects to optical or resist print performance.

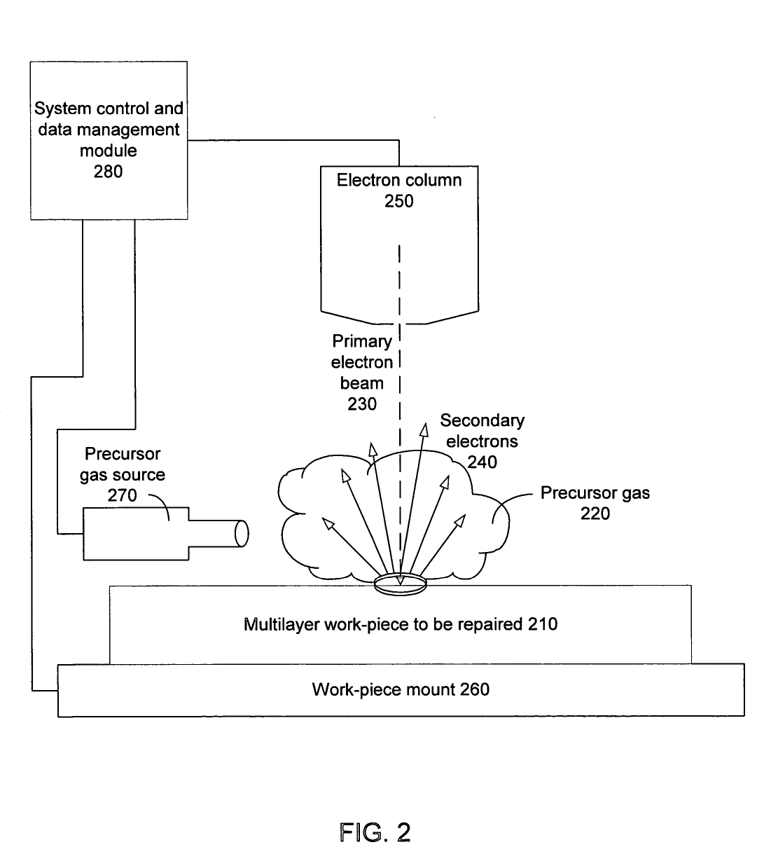

An embodiment of an apparatus for performing localized deposition of capping filling 150 is depicted in FIG. 2. The apparatus comprises work-piece mount 260, precursor gas source 270, electron column 250, and system control and data management module 280. The system control and data management module 280 is coupled to electron column 250, precursor gas source 270 and work-piece mount 260. The multilayer work-piece to be repaired 210 is coupled to the work-piece mount 260. The entire apparatus of FIG. 2 may be enclosed in a vacuum chamber.

The system control and data management module 280 and the work-piece mount 260 position and secure a multilayer work-piece 210 in the path of the electron column 250. The electron column 250 may be an electron optical system comprising an electron source and focusing optical elements. The pinhole 140 may be the target of the electron column 250. The electron column 250 may be electrostatic, electromagnetic, or a combination of the two. For example, the electron column 250 may be similar to that used in a scanning electron microscope (SEM), a transmission electron microscope (TEM), or an instrument that produces a similar electron beam as a SEM or a TEM. The electron column 250 may generate an electron beam with fixed or variable energies. Electron beams are not caustic to multilayers. In contrast, a focused ion beam may penetrate a multilayer surface and cause damage that will result in reflectivity loss. The electron column 250 may be adjusted such that the electron beam is focused and directed to the pinhole location. Adjustments to the electron column 250 may be made by electronics and software of the system control and data management module 280.

For one embodiment of the invention, the pinholes or other types of multilayer defects may be detected by an inspection tool when the multilayer blanks or pattern masks are checked for quality. The inspection tool may be optical, electron microscopic, or mechanical such as a scanning probe microscope. The defect data detected by the inspections may give the location of the defects on the work piece. In addition, the defect data may classify the defect by type and size. The defect data may be transferred to the system control and data management module 280. Based on the defect data, the system control and data management module 280 may help position the multilayer work-piece 210 under the electron column 250 for review and repair.

The multilayer work-piece 210 may be a mask blank or a multilayer blank. A precursor gas source 270 introduces a precursor gas 220 in the immediate area of the multilayer work-piece 210. Thus, the multilayer work-piece 210 is subjected to the precursor gas 220 such that the precursor gas 220 comes into contact with the multilayer work-piece 210. The electron column 250 generates a primary electron beam 230. Secondary electrons 240 are subsequently generated after the primary electron beam 230 contacts the multilayer work-piece 210.

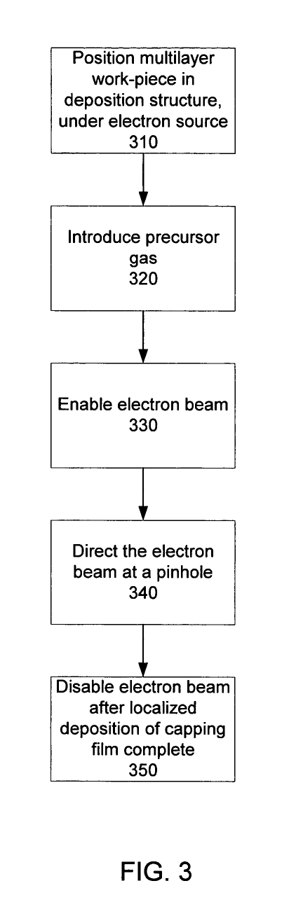

A flowchart of a process to perform localized deposition of capping films to unprotected areas of multilayers is depicted in FIG. 3. A multilayer work-piece 210 is placed in a chamber and mounted to a work-piece mount 260 in operation 310. The work-piece 210 is positioned under an electron column 250 and in the path of an electron beam 230. Alternatively, the electron column 250 may be adjusted to focus and direct the electron beam 230 to the location needing deposition. A precursor gas 220 is introduced into the chamber by a precursor gas source 270 in operation 320.

The precursor gas 220 delivered from the precursor gas source 270 may comprise the capping layer 130 material. The precursor gas 220 may be blended with other carrier gasses to optimize film quality. For example, inert gasses such as nitrogen and argon may be used as carrier gasses. Hydrogen may also be used as a carrier gas to enhance the purity of the deposited material. For one embodiment of the invention, if the capping layer 130 comprises silicon, the precursor gas 220 may comprise silicon. For example, the precursor gas may be SiH₄ or Si₂H₆ if the capping layer 130 comprises silicon.

For another embodiment of the invention, if the capping layer 130 comprises ruthenium, the precursor gas 220 may comprise ruthenium. For example, the precursor gas 220 may be RuF₆, Ru(CO)₅, or Ru₃(CO)₁₂ if the capping material 130 comprises ruthenium.

For yet another embodiment of the invention, if the capping layer 130 comprises carbon, the precursor gas 220 may comprise carbon. For example, if the capping layer 130 comprises carbon, the precursor gas 220 may be CH₄ or any other hydrocarbons.

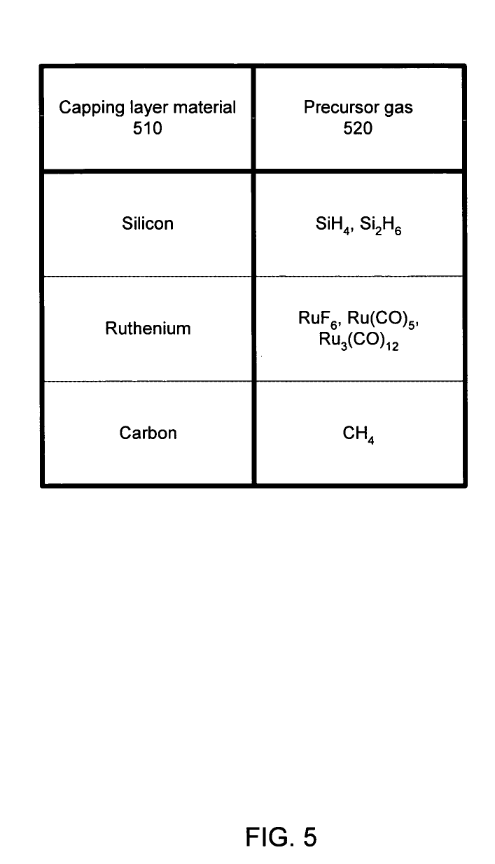

A chart of possible capping layer 130 and precursor gas 220 combinations are listed in FIG. 5. The column 510 provides possible capping layer 130 materials. Column 520 gives the corresponding precursor gas 220 for each capping layer 130 material.

Next, an electron beam is enabled in operation 330. The electron beam is directed at pinhole 140 in operation 340. The electron beam may be scanned to deposit film in any desired shape around the pinhole 140. The film is deposited by the electron beam from a molecular species. The molecular species may comprise a gaseous phase containing the desired elements, such as ruthenium, silicon, carbon, or other composite materials. For one embodiment of the invention, the molecular species is a precursor gas 220.

The electrons from the electron beam 230 induce a chemical reaction at the surface around the pinhole 140 because of the presence of the precursor gas 220. Primary electrons 230 from the electron beam 230 make contact with the target area of the multilayer work-piece 210. However, deposition of the capping filling 150 is mainly provided by energy generated from secondary electrons 240. Secondary electrons 240 emit or rebound from the surface of the multilayer work-piece 210. The secondary electrons 240 provide energy to dissociate the precursor gas 220. During dissociation, electrons crack the bonds of the molecules of the precursor gas 220 or provide the activation energy to break the molecules absorbed on the surface of the multilayer work-piece 210. Once separated, the dissociated molecules form a layer of material on the multilayer surface.

As an example, if the capping layer 130 comprises silicon, the chosen precursor gas 220 may be SiH₄. Primary electrons 230 may be directed at a pinhole 140 of the multilayer work-piece 210. The resulting secondary electrons 240 may cause the precursor gas 220, SiH₄, to dissociate. Therefore, the silicon atoms and the hydrogen atoms of the precursor gas 220 separate. The silicon atoms are left on the surface of the multilayer work-piece 210. The silicon atoms form a capping filling 150 at the pinhole 140. In contrast, the hydrogen atoms are evaporated.

The growth rate and purity of the capping filling 150 may be modulated. The growth rate and purity are functions of electron beam conditions, the multilayer surface conditions, and the precursor gas 220 types and conditions. The electron beam may be adjusted through the voltage, current, and scanning parameters of the electron column 250. The multilayer surface conditions may depend upon cleanliness and surface temperature. Therefore, the multilayer work-piece 210 may be heated to enhance the quality of the repair.

The precursor gas 220 conditions may be adjusted by varying the pressure, flow rate, and flow concentration. The electron beam landing voltage may be in the range of 500 volts to 20,000 volts. Increasing the electron beam landing voltages may provide higher spatial resolution during deposition of the capping filling 150. The electron beam is disabled in operation 340 after the localized deposition of capping film is complete.

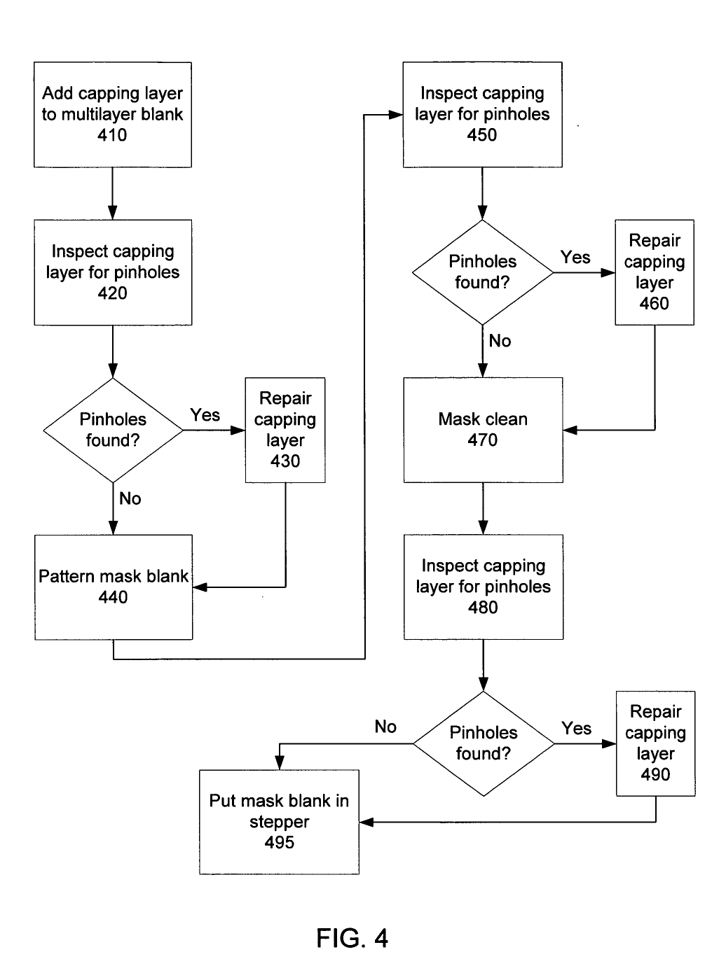

FIG. 4 depicts a flowchart for adding a capping layer 130 to multilayers 120. A capping layer 130 is added to a multilayer blank in operation 410. The capping layer 130 is then inspected for pinholes 140 in operation 420. The inspection process was described above. The inspection may be manually performed or the process may be automated. If no pinholes 140 are found, the mask blank is patterned in operation 440. Mask blank patterning is the process of etching absorber and buffer layers from select areas of the mask blank. If, however, pinholes 140 are found, the capping layer is repaired in operation 430 prior to mask blank patterning. The repair process was described above in FIG. 3.

Following mask blank patterning, the exposed capping layer is again inspected for pinholes 140 in operation 450. As discussed above, over-etching of the buffer and absorber layers on top of the capping layer may cause multilayers to be exposed. Over-etching may occur because the buffer layer, absorber layer, and capping layer often have different etch rates. If no pinholes 140 are found, then the mask blank is cleaned in operation 470. Otherwise, if pinholes 140 are found, the capping layer 130 is repaired prior to the mask clean of operation 470.

After mask clean, the capping layer 130 is again inspected for pinholes 140 in operation 480. If pinholes are not found, the mask blank is ready to be placed in a stepper to image a silicon wafer in operation 495. If pinholes are found, the capping layer 130 is repaired in operation 490 prior to placing the mask blank in the stepper.

In the foregoing specification the invention has been described with reference to specific exemplary embodiments thereof. It will, however, be evident that various modification and changes may be made thereto without departure from the broader spirit and scope of the invention as set forth in the appended claims. The specification and drawings are, accordingly, to be regarded in an illustrative rather than restrictive sense.

1. A method, comprising:
placing a multilayer work-piece having a pinhole in a capping layer to a chamber;
introducing a precursor gas into the chamber in the immediate area of the multilayer work-piece; and
directing an electron beam at the pinhole of the multilayer work-piece.

2. The method of claim 1, wherein the electron beam induces a chemical reaction with the precursor gas that causes the precursor gas to dissociate.

3. The method of claim 1, wherein the capping layer comprises silicon.

4. The method of claim. 3, wherein the precursor gas comprises SiH₄ or Si₂H₆.

5. The method of claim 1, wherein the capping layer comprises ruthenium.

6. The method of claim 5, wherein the precursor gas comprises RuF₆, Ru(CO)₅, or Ru₃(CO)₁₂.

7. The method of claim 1, wherein the capping layer comprises carbon.

8. The method of claim 7, wherein the precursor gas comprises CH₄ or any other hydrocarbon.

9. The method of claim 1, wherein the multilayer work-piece is a mask blank.

10. The method of claim 1, wherein the multilayer work-piece is a multilayer blank.

11. A method, comprising:
adding a capping layer to an extreme ultraviolet (EUV) mask comprising reflective multilayer deposited on a substrate;
inspecting the capping layer for a first pinhole; and
depositing a first capping filling at the first pinhole.

12. The method of claim 11, wherein the deposition of the first capping filling is performed by directing an electron beam at the pinhole in the presence of a precursor gas.

13. The method of claim 12, wherein the capping layer comprises silicon and the precursor gas comprises SiH₄.

14. The method of claim 12, further comprising:
etching an absorber layer and a buffer layer to form a patterned mask;
inspecting the capping layer for a second pinhole; and
depositing a second capping filling at the second pinhole.

15. The method of claim 14, further comprising:
cleaning the EUV mask surface;
inspecting the capping layer for a third pinhole; and
depositing a third capping filling at the third pinhole.

16. The method of claim 12, wherein the electron beam is generated by an electron optical system.

17. The method of claim 15, further comprising:
modulating a growth rate of the first capping filling by adjusting a voltage of the electron beam.

18. The method of claim 17, further comprising:
increasing the voltage of the electron beam to increase a spatial resolution of the first capping filling.

19. An apparatus, comprising:
a work-piece mount to secure a extreme ultraviolet (EUV) multilayer work-piece; and
an electron source to provide an electron beam at a capping layer pinhole of the multilayer work-piece, wherein the electron source is adjustable to focus and direct the electron beam at the pinhole.

20. The apparatus of claim 19, further comprising:
a gas source to generate a precursor gas, wherein the precursor gas contacts the multilayer work-piece, wherein the electron beam dissociates the precursor gas to form a filling material at the pinhole.

21. The apparatus of claim 19, wherein the electron beam has a landing voltage between 500 volts and 20,000 volts.

22. The apparatus of claim 19, wherein the work-piece mount is enclosed in a chamber.

23. The apparatus of claim 20, wherein the electron beam is scanned to deposit a film in a desired shape.

24. The apparatus of claim 20, wherein the precursor gas comprises ruthenium.

25. The apparatus of claim 20, wherein the precursor gas comprises silicon.

26. The apparatus of claim 20, wherein the precursor gas comprises carbon.

27. An extreme ultraviolet (EUV) mask blank, comprising:
means for inspecting the EUV mask blank for defects;
means for localized deposition of a capping filling in the pinholes; and
means for heating the EUV mask blank to enhance repair quality.

28. The EUV mask blank of claim 27, further comprising:
means for selecting a precursor gas.

29. The EUV mask blank of claim 27, further comprising:
means for modulating spatial resolution of the capping filling.

30. The EUV mask blank of claim 27, further comprising:
means for modulating the growth rate and purity of the capping filling.
